(19) United States
(12) Patent Application Publication
(10) Pub. No.: US 2025/0125197 A1
(43) Pub. Date: Apr. 17, 2025

(54) SEMICONDUCTOR CHIP

(71) Applicant: Samsung Electronics Co., Ltd., Suwon-si (KR)

(72) Inventors: Junyun Kweon, Suwon-si (KR); Wooju Kim, Suwon-si (KR); Junho Yoon, Suwon-si (KR); Dayoung Cho, Suwon-si (KR); Jinwook Hong, Suwon-si (KR)

(21) Appl. No.: 18/884,732

(22) Filed: Sep. 13, 2024

(30) Foreign Application Priority Data
Oct. 17, 2023 (KR) 10-2023-0138925

(51) Int. Cl. H01L 21/78; B23K 26/38; B23K 101/40; H01L 21/02; H01L 21/304; H01L 21/683

(52) U.S. Cl. CPC H01L 21/78; B23K 26/38; H01L 21/02013; H01L 21/02021; H01L 21/304; H01L 21/6836; B23K 2101/40; H01L 2221/68327

(57) ABSTRACT

A semiconductor chip includes a base substrate including a first surface, a second surface opposite to the first surface, and a sidewall extending between the first surface and the second surface, and a device layer on the first surface of the base substrate, wherein the base substrate includes a stress relief region within a first depth from the second surface and a second depth from the sidewall, and at least a portion of the sidewall of the base substrate is recessed inward from the sidewall of the device layer.

### CROSS-REFERENCE TO RELATED APPLICATION

This application is based on and claims priority under 35 U.S.C. § 119 to Korean Patent Application No. 10-2023-0138925, filed on Oct. 17, 2023 in the Korean Intellectual Property Office, the disclosure of which is incorporated by reference herein in its entirety.

### BACKGROUND

The inventive concept relates to a semiconductor chip, and more particularly, to a semiconductor chip manufactured by a method of manufacturing a semiconductor chip using a wafer dicing method.

In a semiconductor chip manufacturing process, a surface of a semiconductor wafer is divided into a plurality of regions by scribe lane regions arranged in a grid form on the surface of the semiconductor wafer that is disk-shaped, and semiconductor devices such as integrated circuit devices or memory devices are formed in the divided regions. Individual semiconductor chips are manufactured by cutting the semiconductor wafer along scribe lane regions to singulate the regions in which the semiconductor devices are formed.

In the process of singulating the semiconductor wafer, a wafer dicing process using a laser beam is used. In a conventional wafer dicing process using a laser beam, a workpiece is cut by heating and melting the workpiece by irradiating laser light in a high absorption wavelength band on the workpiece. In this case, there is a problem that not only the cut region but also a surrounding region is melted, thereby damaging some of the semiconductor devices formed on the wafer. To solve this problem, a stealth dicing process is used to induce internal cracks by focusing a laser beam onto the wafer.

### SUMMARY

The inventive concept provides a semiconductor chip manufactured by a method of manufacturing a semiconductor chip using a wafer dicing method with improved reliability.

According to an aspect of the inventive concept, there is provided a semiconductor chip including a base substrate including a first surface, a second surface opposite to the first surface, and a sidewall extending between the first surface and the second surface, and a device layer on the first surface of the base substrate, wherein the base substrate includes a stress relief region within a first depth from the second surface and a second depth from the sidewall, and at least a portion of the sidewall of the base substrate is recessed inward from a sidewall of the device layer.

According to another aspect of the inventive concept, there is provided a semiconductor chip including a base substrate including a chip region, a scribe lane region surrounding the chip region, and first and second surfaces opposite to each other, and a device layer on the first surface of the base substrate, wherein the base substrate includes a plurality of modified layers within the scribe lane region that are spaced apart from each other in a lateral direction, and at least a portion of a sidewall of the base substrate is recessed inward from a sidewall of the device layer.

According to another aspect of the inventive concept, there is provided a semiconductor chip including a base substrate including a chip region, a scribe lane region surrounding the chip region, and first and second surfaces opposite to each other, and a device layer on the first surface of the base substrate, wherein the base substrate further includes a plurality of modified layers within the scribe lane region that are spaced apart from each other in a lateral direction, a stress relief region within a first depth from the second surface and a second depth from a sidewall of the base substrate, and a rounded chamfer portion in a boundary region between the second surface of the base substrate and the sidewall of the base substrate, wherein at least a portion of the sidewall of the base substrate is horizontally offset inward from a sidewall of the device layer.

### BRIEF DESCRIPTION OF THE DRAWINGS

Embodiments of the inventive concept will be more clearly understood from the following detailed description taken in conjunction with the accompanying drawings in which:

FIG. 1 is a perspective view illustrating a semiconductor chip according to some embodiments;

FIG. 2 is a cross-sectional view taken along line A-A′ of FIG. 1;

FIG. 3 is a schematic plan view illustrating a base substrate of a semiconductor chip;

FIG. 4 is a cross-sectional view illustrating a semiconductor chip according to some embodiments;

FIG. 5 is a cross-sectional view illustrating a semiconductor chip according to some embodiments;

FIG. 6 is a flowchart illustrating a method of manufacturing a semiconductor chip according to some embodiments;

FIGS. 7A, 7B, 7C, 8A, 8B, 9, 10, 11A, 11B, and 12 are schematic diagrams illustrating a method of manufacturing a semiconductor chip according to some embodiments; and

FIGS. 13 to 16 are schematic diagrams illustrating a method of manufacturing a semiconductor chip according to some embodiments.

### DETAILED DESCRIPTION

Hereinafter, embodiments of the inventive concept will be described in detail with reference to the accompanying drawings.

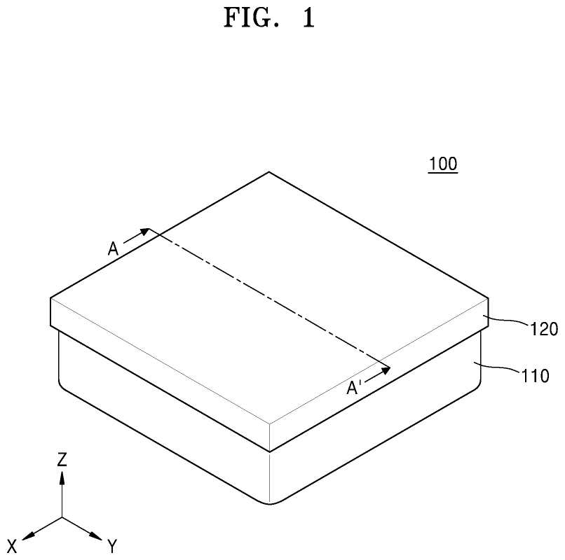

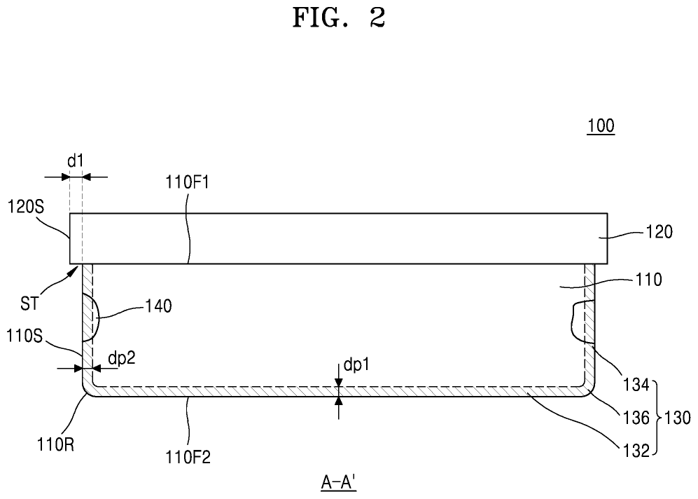

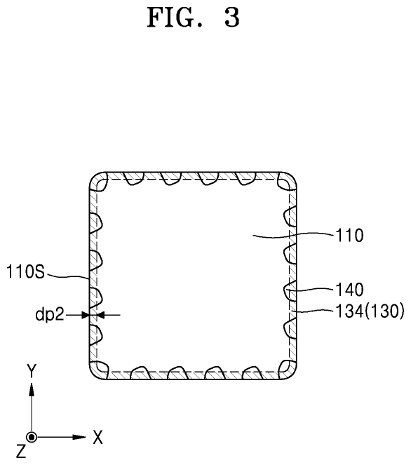

FIG. 1 is a perspective view illustrating a semiconductor chip 100 according to some embodiments. FIG. 2 is a cross-sectional view taken along line A-A′ of FIG. 1. FIG. 3 is a schematic plan view illustrating a base substrate 110 of the semiconductor chip 100.

Referring to FIGS. 1 to 3, the semiconductor chip 100 may include the base substrate 110 and a device layer 120 arranged on the base substrate 110.

The base substrate 110 may include silicon (Si). However, the material of the base substrate 110 is not limited to silicon. For example, the base substrate 110 may include other semiconductor elements such as germanium (Ge), or compound semiconductors such as SiC, GaAs, InAs, InP, etc. The base substrate 110 may have a silicon-on-insulator (SOI) structure. For example, the base substrate 110 may include a buried oxide (BOX) layer. The base substrate 110 may be referred to as an inactive layer of the semiconductor chip 100.

The base substrate 110 may include a first surface 110F1, a second surface 110F2, and a sidewall 110S. The first surface 110F1 and the second surface 110F2 may be arranged opposite to each other. Both the first surface 110F1 and the second surface 110F2 may extend in a first horizontal direction X and a second horizontal direction Y. The sidewall 110S may extend in a vertical direction Z between the first surface 110F1 and the second surface 110F2.

In some embodiments, the base substrate 110 may further include a rounded chamfer portion 110R in a boundary region between the second surface 110F2 and the sidewall 110S. For example, the rounded chamfer portion 110R may indicate a corner adjacent to the second surface 110F2, at least partially composed of a curved surface.

The device layer 120 may be arranged on the first surface 110F1 of the base substrate 110. The device layer 120 may be referred to as an active layer of the semiconductor chip 100.

In some embodiments, the device layer 120 may include various types of individual devices. The plurality of individual devices may include various microelectronics, for example, a metal-oxide-semiconductor field effect transistor (MOSFET) such as a complementary metal-oxide-semiconductor transistor (CMOS transistor), a system LSI (large scale integration), an image sensor such as a CMOS imaging sensor (CIS), etc., a micro-electro-mechanical system (MEMS), an active device, a passive device, etc.

In some embodiments, the device layer 120 may include a plurality of memory devices. The memory devices may include Dynamic Random Access Memory (DRAM), Static Random Access Memory (SRAM), flash memory, Electrically Erasable Programmable Read Only Memory (EEPROM), Phase Change Random Access Memory (PRAM), Magnetic Random Access Memory (MRAM), or Resistive Random Access Memory (RRAM) devices.

In some embodiments, the device layer 120 may include a plurality of logic devices. The logic devices may include AND, NAND, OR, NOR, exclusive OR (XOR), exclusive NOR (XNOR), inverter (INV), adder (ADD), buffer, delay (DLY), filter (FIL), multiplexer (MXT/MXIT), OR/AND/INVERTER (OAI), AND/OR (AO), AND/OR/INVERTER (AOI), D flip-flop, reset flip-flop, master-slave flip-flop, latch, counter, or buffer devices. In addition, the logic devices may include a Central Processing Unit (CPU), a micro-processor unit (MPU), a graphic processing unit (GPU), an Application Processor (AP), or the like.

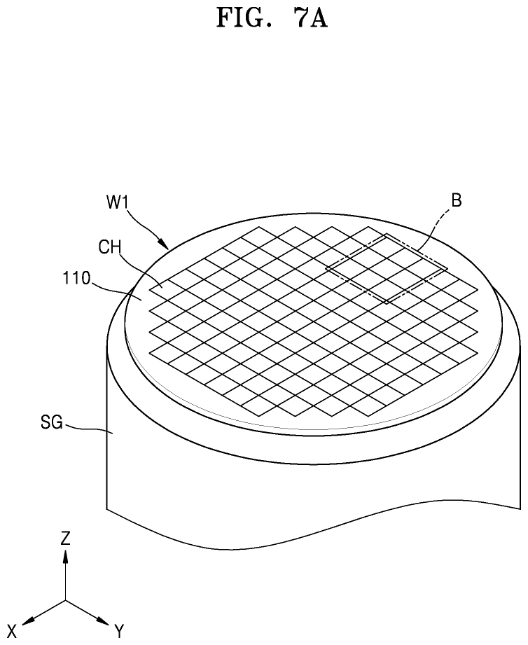

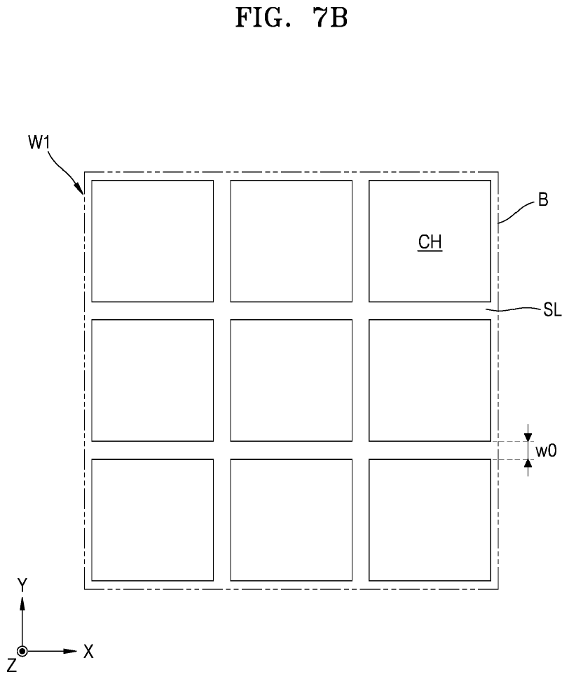

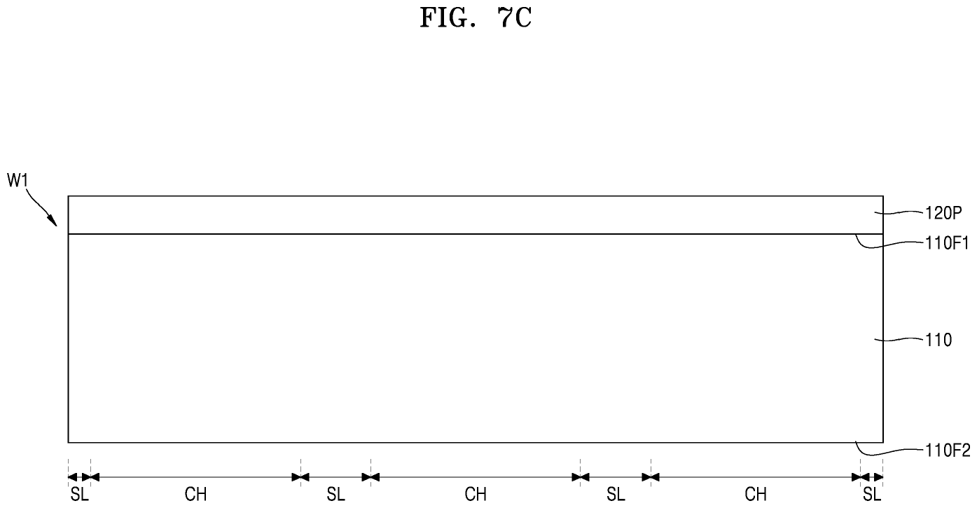

The base substrate 110 may include a chip region CH (see FIG. 7B) and a scribe lane region SL (see FIG. 7B) surrounding the chip region CH in a plane. For example, the semiconductor chip 100 may be formed by forming multiple device layers on a wafer and singulating the wafer by a dicing process thereafter, and the base substrate 110 may be, for example, a portion of the wafer. For example, the dicing process may be performed to singulate the wafer along the scribe lane region, and for example, the dicing process may include a stealth dicing process using a laser. Accordingly, the sidewall 110S of the base substrate 110 may correspond to a portion of a wafer arranged in the scribe lane region.

The base substrate 110 may further include a stress relief region 130 arranged within a first depth dp1 from the second surface 110F2 and within a second depth dp2 from the sidewall 110S. The stress relief region 130 may indicate a portion within the wafer or a portion of the base substrate 110 formed by performing a surface treatment process on the surface of the divided or split wafer after splitting the wafer by a dicing process.

For example, the stress relief region 130 may be formed by performing a surface treatment process on the second surface 110F2 of the base substrate 110 and/or the sidewall 110S of the base substrate 110, and may include a surface region of the base substrate 110 after defect components such as crack-causing defects or chipping-causing defects are removed by performing a surface treatment process on the second surface 110F2 of the base substrate 110 and/or on the sidewall 110S of the base substrate 110. The surface region of the base substrate 110 may indicate portions of the inside of the base substrate 110 adjacent to the surface (the sidewall 110S and the second surface 110F2) of the base substrate 110.

The stress relief region 130 may include a rear region 132, a side region 134, and a connection portion 136.

The rear region 132 may be arranged within the first depth dp1 of the base substrate 110. The rear region 132 may be an region inside the base substrate 110 adjacent to the second surface 110F2 of the base substrate 110 after a surface treatment process, and may be a surface region in which defect components such as a crack-causing defect or a chipping-causing defect have been removed from the second surface 110F2 of the base substrate 110. For example, the rear region 132 may be a planarized region formed on the second surface 110F2 of the base substrate 110 and may be a region with reduced surface roughness. For example, the first depth dp1 may be in a range of about 1 nanometer to about 100 nanometers, but is not limited thereto.

The side region 134 may be arranged within the second depth dp2 from the sidewall 110S of the base substrate 110. The side region 134 may be a region inside the base substrate 110 adjacent to the sidewall 110S of the base substrate 110 after the surface treatment process, or a surface region in which defect components such as a crack-causing defect or a chipping-causing defect have been removed from the sidewall 110S of the base substrate 110. For example, the side region 134 may be a planarized region formed on the sidewall 110S of the base substrate 110 and may be a region with reduced surface roughness. For example, the second depth dp2 may be in a range of about 1 nanometer to about 100 nanometers, but is not limited thereto. For example, the side region 134 may be a portion arranged within the scribe lane region of the base substrate 110.

The rear region 132 of the stress relief region 130 may be connected to the side region 134 of the stress relief region 130. For example, the rear region 132 of the stress relief region 130 may be connected to the side region 134 of the stress relief region 130 by the connection portion 136. The connection portion 136 arranged between the rear region 132 of the stress relief region 130 and the side region 134 of the stress relief region 130 may be arranged along the shape of the rounded chamfer portion 110R. For example, the connection portion 136 may be conformally formed to a relatively uniform depth along the curved shape of the rounded chamfer portion 110R.

In some embodiments, the rounded chamfer portion 110R of the base substrate 110 may be formed by performing a surface treatment process on the second surface 110F2 of the base substrate 110 and/or on the sidewall 110S of the base substrate 110. The connection portion 136 of the stress relief region 130 may indicate a surface region of the base substrate 110 after defect components such as crack-causing defects or chipping-causing defects have been removed by performing a surface treatment process on the second surface 110F2 of the base substrate 110 and/or on the sidewall 110S of the base substrate 110.

In some embodiments, the base substrate 110 may further include a plurality of modified layers 140. The plurality of modified layers 140 may be arranged to be laterally spaced apart in the scribe lane region. For example, the plurality of modified layers 140 may be arranged at four corners of the base substrate 110, as shown in FIG. 3, and may be arranged at a predetermined interval along the sidewall 110S of the base substrate 110.

For example, the plurality of modified layers 140 may be regions in which phase change occurs due to irradiation of laser light in a wafer dicing process. For example, the plurality of modified layers 140 may be a region modified into amorphous silicon by irradiation of laser light in the wafer dicing process, and the wafer may be divided by the generation of stress due to the plurality of modified layers 140. At least a portion of a plurality of modified layers 140 may be arranged to vertically overlap the side region 134 of the stress relief region 130.

For example, a portion of the modified layer 140 vertically overlapping the side region 134 of the stress relief region 130 may be a region where a crack-causing defect or a chipping-causing defect has been removed by a surface treatment process, and may be a region flattened or a region with reduced surface roughness.

As illustrated in FIG. 2, at least a portion of the sidewall 110S of the base substrate 110 may be recessed (or horizontally offset) inward from the sidewall 120S of the device layer 120, and a stepped portion ST may be defined in a boundary region between the sidewall 110S of the base substrate 110 and the sidewall 120S of the device layer 120. In other words, the sidewall 120S of the device layer 120 may protrude outward with respect to the sidewall 110S of the base substrate 110. In addition, a portion of the bottom surface of the device layer 120 in the stepped portion ST may be exposed to the outside without being covered by the base substrate 110. In some embodiments, a distance d1 in the horizontal direction between at least a portion of the sidewall 110S of the base substrate 110 and the sidewall 120S of the device layer 120 may range from about 1 micrometer to about 5 micrometers.

According to some embodiments, the stress relief region 130 may be formed on the sidewall 110S and the second surface 110F2 of the base substrate 110, by a surface treatment process and accordingly, crack-causing defects or chipping-causing defects that may be generated after the wafer dicing process may be removed from the sidewall 110S and the second surface 110F2 of the base substrate 110, thereby improving the reliability of the wafer dicing process.

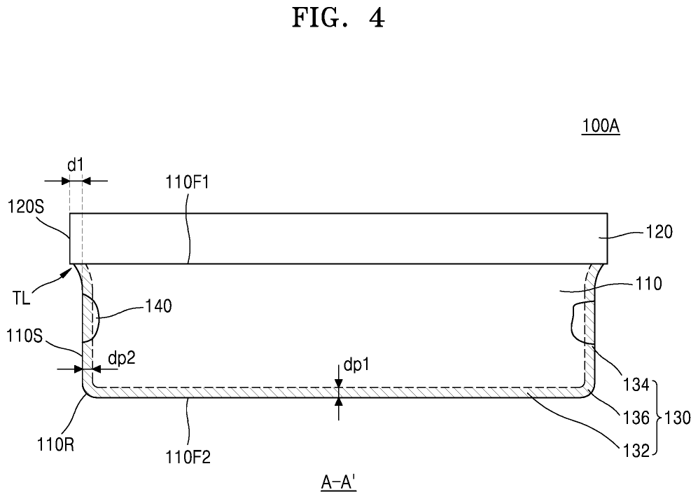

FIG. 4 is a cross-sectional view illustrating a semiconductor chip 100A according to some embodiments. In FIG. 4, the same reference numerals as in FIGS. 1 to 3 indicate the same components.

Referring to FIG. 4, a tail portion TL may be defined in a boundary region between a sidewall 120S of the device layer 120 and a sidewall 110S of the base substrate 110. The tail portion TL may indicate a portion of the base substrate 110 adjacent to the sidewall 120S of the device layer 120 and the first surface 110F1 of the base substrate 110. The tail portion TL may protrude outward as it approaches the first surface 110F1 of the base substrate 110 to indicate an edge region of the base substrate 110 arranged adjacent to the sidewall 120S of the device layer 120. Unlike the semiconductor chip 100 illustrated in FIG. 2, the bottom surface of the edge region of the device layer 120 may be covered by the tail portion TL and may not be exposed to the outside. The tail portion TL may include an angled or curved portion that bends or curves outwardly between a straight portion (e.g., vertical portion) of the sidewall 110S of the base substrate 110 and a bottom surface of the device layer 120.

The stress relief region 130 may be arranged within the first depth dp1 from the second surface 110F2 of the base substrate 110 and within the second depth dp2 from the sidewall 110S of the base substrate 110. The stress relief region 130 may be formed to a conformal thickness from the surface of the tail portion TL and may be arranged, for example, within the second depth dp2 from the surface of the tail portion TL.

According to some embodiments, the stress relief region 130 may be formed by performing a surface treatment process on the second surface 110F2 of the base substrate 110 and/or the sidewall 110S of the base substrate 110, and for example, the surface treatment process may include at least one of a plasma etching process, a wet etching process, and a wet cleaning process. The tail portion TL may be formed on the sidewall 110S of the base substrate 110 according to the process conditions and properties of the surface treatment process performed on the second surface 110F2 of the base substrate 110 and/or the sidewall 110S of the base substrate 110.

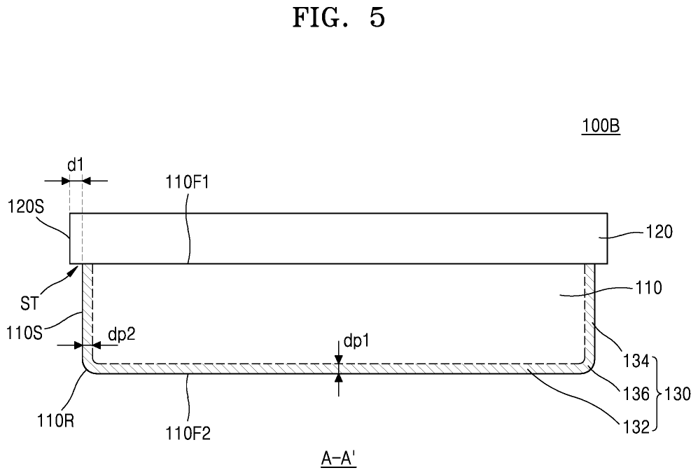

FIG. 5 is a cross-sectional view illustrating a semiconductor chip 100B according to some embodiments. In FIG. 5, the same reference numerals as in FIGS. 1 to 4 indicate the same components.

Referring to FIG. 5, the semiconductor chip 100B may be different from the semiconductor chip 100 described with reference to FIGS. 1 to 3 in that a base substrate 110 of FIG. 5 does not include the modified layer 140 of FIGS. 2 to 4. The base substrate 110 may have a relatively low height, and for example, may have a lower height than the base substrate 110 included in the semiconductor chip 100 described with reference to FIGS. 1 to 3.

According to some embodiments, the wafer may be thinned by forming the modified layer 140 on the wafer, dividing the wafer by the stress applied to the modified layer 140, and then removing the rear surface of the wafer through a grinding process. When a sufficiently large amount (or a sufficiently large height) of the rear portion of the wafer is removed so as to remove all the modified layers in the wafer thinning process, the modified layer 140 may not remain inside the base substrate 110 adjacent to the sidewall 110S of the base substrate 110.

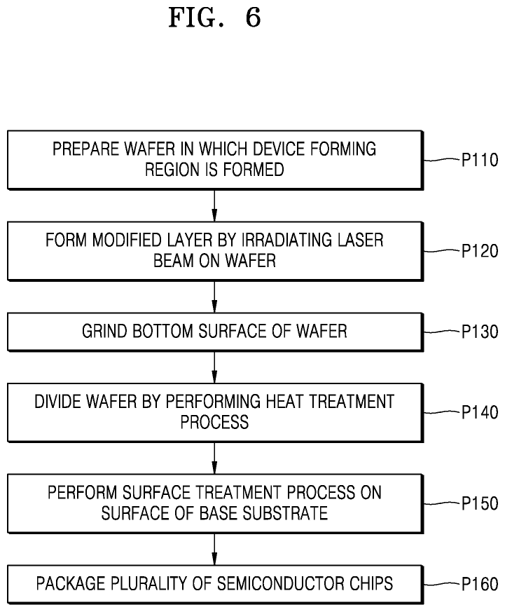

FIG. 6 is a flowchart illustrating a method of manufacturing a semiconductor chip according to some embodiments. FIGS. 7A, 7B, 7C, 8A, 8B, 9, 10, 11A, 11B, and 12 are schematic diagrams illustrating a method of manufacturing a semiconductor chip according to some embodiments.

Referring to FIGS. 6 and 7A, 7B, and 7C, a wafer W1 on which a device forming region 120P is formed is prepared (operation P110).

The wafer W1 may include a plurality of chip regions CH and a scribe lane region SL surrounding each chip region CH in a plan view. For example, the plurality of chip regions CH may be arranged in a matrix shape in a first horizontal direction X and a second horizontal direction Y, and the scribe lane region SL may be arranged between two adjacent chip regions CH. The scribe lane region SL may extend in the first horizontal direction X and the second horizontal direction Y. The scribe lane region SL may have a first width w0.

In some embodiments, the wafer W1 may include a base substrate 110 and a device forming region 120P arranged on the base substrate 110. The base substrate 110 includes a first surface 110F1 and a second surface 110F2, and a device forming region 120P may be formed on the first surface 110F1 of the base substrate 110.

The device forming region 120P may include a plurality of individual devices formed at positions corresponding to each of the plurality of chip regions CH, and the plurality of individual devices may include, for example, at least one of memory devices, logic devices, and various types of passive devices.

In some embodiments, the process of forming the device forming region 120P may be an oxidation process for forming an oxide layer, a lithography process including spin coating, exposure and development, a thin layer deposition process, a dry or wet etching process, a metal-wiring forming process, and the like.

The oxidation process may be a process in which oxygen or water vapor is chemically reacted with the silicon substrate surface at a high temperature of about 800° C. to about 1200° C. to form a thin and uniform silicon oxide layer. The oxidation process may include dry oxidation and wet oxidation. The dry oxidation may react with oxygen gas to form an oxide layer, and the wet oxidation may react with oxygen and water vapor to form an oxide layer.

The lithography process may be a process of transferring a circuit pattern previously formed on the lithography mask to a substrate through exposure. The lithography process may be performed in the order of spin coating, exposure, and development processes.

For example, the thin layer deposition process may be any one of atomic layer deposition (ALD), chemical vapor deposition (CVD), plasma-enhanced CVD (PECVD), metal organic CVD (MOCVD), physical vapor deposition (PVD), reactive pulsed laser deposition, molecular beam epitaxy, and DC magnetron sputtering.

The dry etching process may be, for example, any one of reactive ion etching (RIE), deep RIE (DRIE), ion beam etching (IBE), and Ar milling. As another example, the dry etching process that may be performed on the wafer W1 may be atomic layer etching (ALE). In addition, at least one of Cl₂, HCl, CHF₃, CH₂F₂, CH₃F, H₂, BCL₃, SiCl₄, Br₂, HBr, NF₃, CF₄, C₂F₆, C₄F₈, SF₆, O₂, SO₂, and carbonyl sulfide (COS) may be used as etchant gas in the dry etching process that may be performed on the wafer W1.

The metal wiring process may be a process of forming a conductive wiring (metal line) to implement a circuit pattern for operating the plurality of individual devices. Ground, power, and signal transfer paths for operating the plurality of individual devices may be formed by the metal wiring process. The metal wiring may include at least one metal element from among Au, Pt, Ag, Cu, Al, Ti, Ta, and W.

In some embodiments, in the process of forming the device forming region 120P, a flattening process such as a chemical mechanical polishing (CMP) process or an etchback process, or an ion implantation process may be performed.

The wafer W1 may be arranged on a stage SG. The stage SG may support the wafer W1 processed using a laser. In some embodiments, the stage SG may be or include a vacuum chuck configured to support the wafer W1 using a vacuum pressure. Alternatively, the stage SG may be or include an electrostatic chuck configured to support the wafer W1 using an electrostatic force, or a chuck including a clamp mechanism to physically support the wafer W1.

The stage SG may include a stage driver for moving and rotating the stage SG. While the wafer W1 is being processed using a laser, the stage SG may be configured to move and/or rotate while supporting the wafer W1 by an actuator included in the stage driving unit.

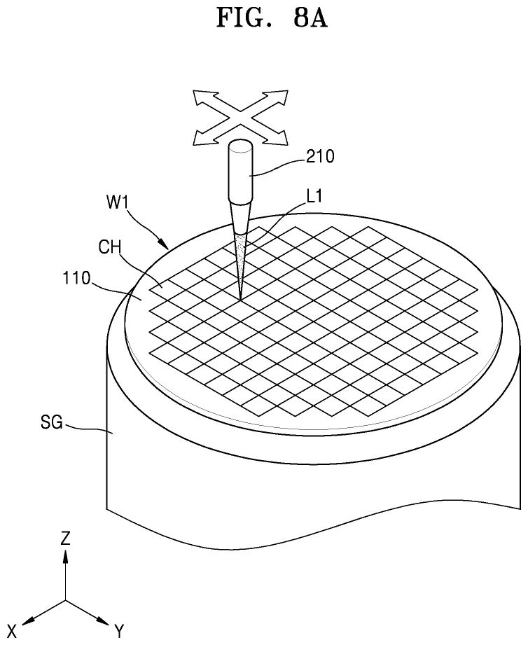

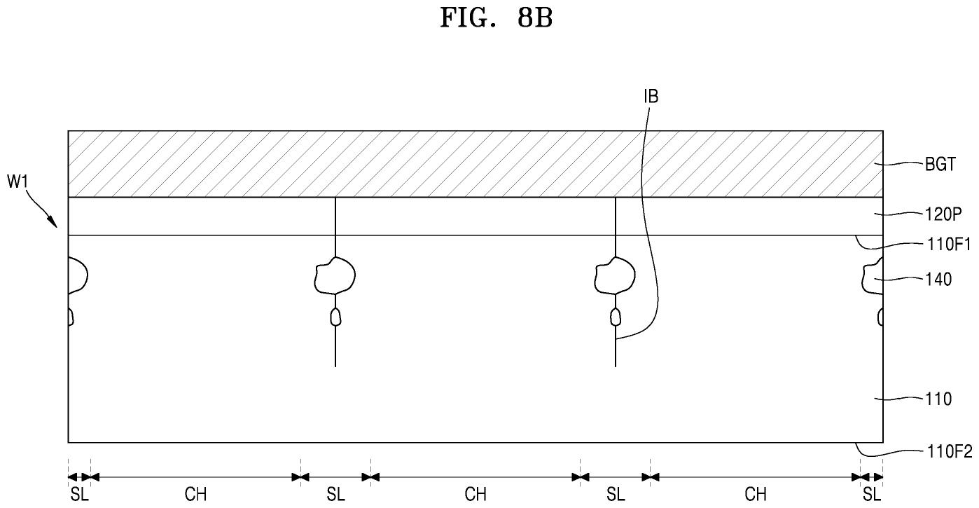

Referring to FIGS. 6, 8A, and 8B, a modified layer 140 may be formed in the wafer W1 by irradiating a laser beam L1 on the wafer W1 (operation P120).

In some embodiments, the laser beam L1 may be irradiated onto the front face of the wafer W1 by using a laser device 210. The laser device 210 may be configured to condense the laser beam LI inside the wafer W1. For example, the laser device 210 may include a light source and a condensing optical system, and the condensing optical system may be configured to be connected to a predetermined actuator and move so that the laser beam L1 emitted from the light source is concentrated at a target position inside the wafer W1.

The laser device 210 may be configured to irradiate the laser beam L1 to a target position inside the wafer W1 while moving the laser beam L1 along the scribe lane region SL of the wafer W1. For example, the laser beam L1 may be irradiated to the wafer W1 while the laser device 210 is fixed, but the stage SG may move in a horizontal direction (e.g., X direction and/or Y direction) so that the laser beam L1 may be irradiated along the scribe lane region SL of the wafer W1. Alternatively, while the stage SG is fixed, the laser device 210 may supply the laser beam L1 to the wafer W1 while moving in the horizontal direction (e.g., X direction and/or Y direction) along the scribe lane region SL of the wafer W1. In other embodiments, in order to irradiate the laser beam L1 along the scribe lane region SL of the wafer W1, the movement of the laser device 210 and the movement of the stage SG may be parallel.

In some embodiments, the laser device 210 may be a laser dicing device using stealth dicing technology, and for example, the stealth dicing technology may be a technology of focusing a laser beam in a wavelength band (i.e., a wavelength band with a low absorption rate of the wafer W1) capable of transmitting the wafer W1 on a point in place inside the wafer W1 through the surface of the wafer W1.

In some embodiments, the laser beam L1 may be repeatedly irradiated with a pulse that lasts for a very short time (e.g., 1 μs or less), and may be focused on a narrow region on the wafer W1. The laser beam L1 may have a high peak power density of, for example, about 1×10⁸ W/cm² spatially (through focusing) and temporally (through pulsing) near the focal point or target position set inside the wafer W1.

The modified layer 140 and an internal crack IB may be formed in the scribe lane region SL of the wafer W1 by irradiation of the laser beam L1. The modified layer 140 may indicate a region in which a semiconductor material (e.g., single crystalline silicon) constituting the base substrate 110 is phase-changed into amorphous silicon by local heat generated by irradiation of the laser beam L1. By the formation of the modified layer 140, the internal crack IB may be formed around the modified layer 140 mainly in a vertical direction.

In some embodiments, the laser beam L1 may be irradiated to a plurality of irradiation points along the scribe lane region SL of the wafer W1, and a plurality of modified layers 140 may be formed at the plurality of irradiation points to which the laser beam L1 is irradiated. For example, the plurality of modified layers 140 may be spaced apart in the horizontal direction (X direction or Y direction), and may also be arranged at four corners of each chip region CH, for example, at the intersections of the scribe lane region SL extending in the first horizontal direction X and the scribe lane region SL extending in the second horizontal direction Y.

In some embodiments, an additional cutting process may be performed before irradiating the laser beam L1 or after irradiating the laser beam L1. For example, the additional cutting process may be a process for forming a groove or recess in the device forming region 120P in the scribe lane region SL. The additional cutting process may include a laser grooving process or a blade cutting process.

Thereafter, a protective tape BGT may be attached to the top surface of the wafer W1. For example, the protective tape BGT may be attached to a top surface of the device forming region 120P.

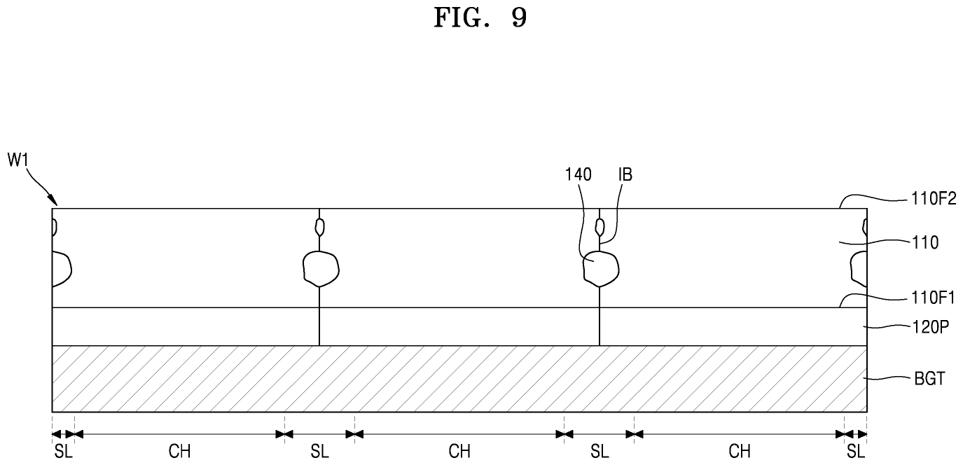

Referring to FIGS. 6 and 9, the thickness of the base substrate 110 may be reduced from the second surface 110F2 of the base substrate 110 by grinding the bottom surface of the wafer W1 (operation P130).

In some embodiments, in order to grind the bottom surface of the wafer W1, a predetermined wafer W1 may be flipped and mounted on the stage SG so that the bottom surface of the wafer W1 faces upward. For example, the wafer W1 may be arranged so that the second surface 110F2 of the base substrate 110 faces upward and the protective tape BGT is arranged between the wafer W1 and the stage SG. Thereafter, the stage SG supporting the wafer W1 and/or the grinding device may be rotated to grind the bottom surface of the wafer W1 to form the base substrate 110 in a set thickness. In some embodiments, a portion of the modified layer 140 may be removed through a grinding process. In some embodiments, the grinding process may be a chemical mechanical polishing (CMP) process.

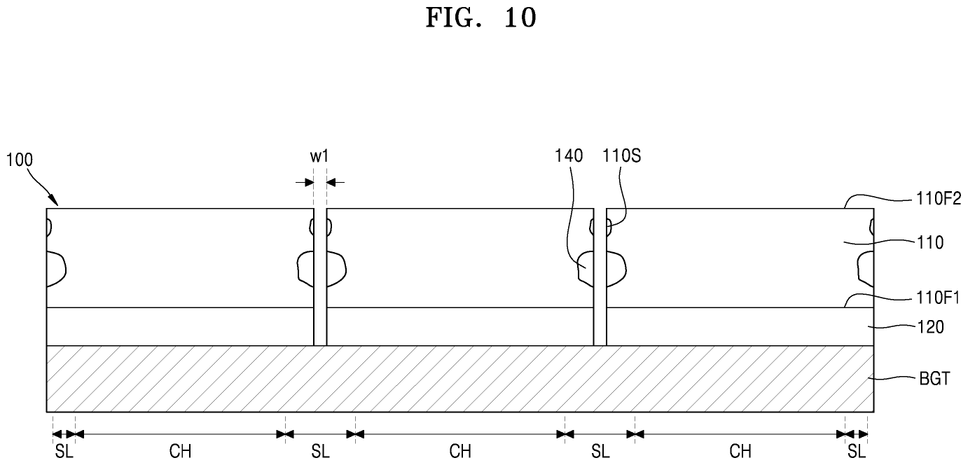

Referring to FIGS. 6 and 10, a heat treatment process may be performed to extend or expand the protective tape BGT and divide the wafer W1 (operation P140).

In some embodiments, by performing heat treatment on the protective tape BGT, the protective tape BGT may be extended to a certain width in the horizontal direction, and accordingly, the base substrate 110 may be divided or singulated along the internal crack IB. In this case, the wafer W1 may be singulated and separated into a plurality of semiconductor chips 100 by the internal crack IB in the scribe lane region SL.

In some embodiments, the plurality of semiconductor chips 100 may be arranged to be spaced apart in the horizontal direction (X direction or Y direction) while the sidewall 110S and the second surface 110F2 of the base substrate 110 are exposed, and the device layer 120 is attached to the protective tape BGT.

In some embodiments, the heat treatment process may be performed at a temperature of about 30° C. to about 200° C. for several seconds to several hours. For example, the conditions of the heat treatment process may be selected so that the plurality of semiconductor chips 100 may be spaced apart from each other at a first interval w1. For example, the conditions of the heat treatment process may be selected so that the plurality of semiconductor chips 100 may be spaced apart at a first interval w1 of hundreds of nanometers to several micrometers.

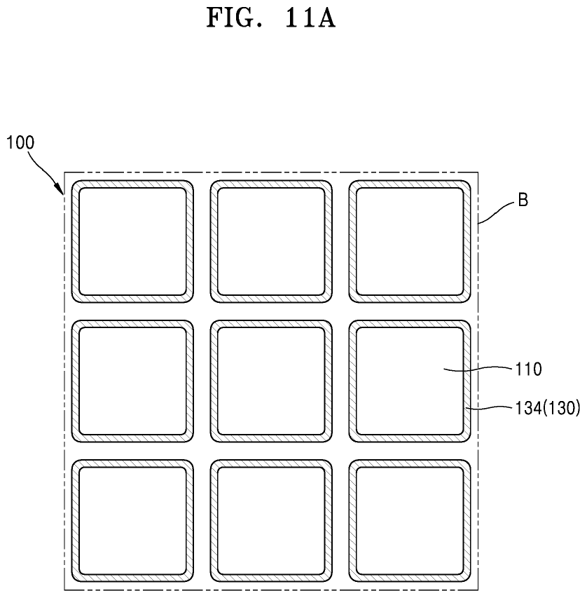

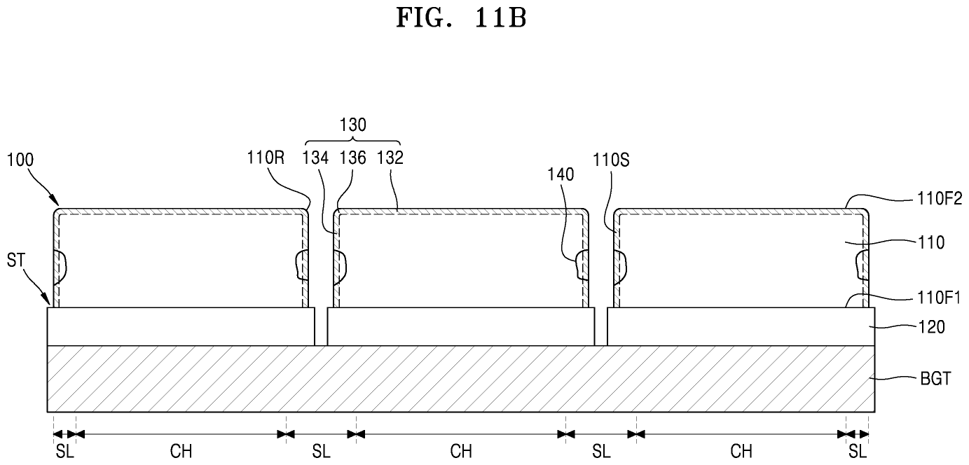

Referring to FIGS. 6, 11A, and 11B, a stress relief region 130 may be formed by performing a surface treatment process on the second surface 110F2 and the sidewall 110S of the base substrate 110 (operation P150).

In some embodiments, the surface treatment process may include at least one of a plasma etching process, a wet etching process, wet cleaning process, and the like. The surface treatment process may form a stress relief region 130 within a first depth dp1 from the second surface 110F2 of the base substrate 110 and a second depth dp2 from the sidewall 110S of the base substrate 110, and for example, the stress relief region 130 may indicate a region from which defect components such as a crack-causing defect or a chipping-causing defect present in a portion adjacent to the modified layer 140 or the internal crack IB have been removed. In addition, the stress relief region 130 may be a planarized region formed within the first depth dp1 (see FIG. 2) from the second surface 110F2 of the base substrate 110 and the second depth dp2 (see FIG. 2) from the sidewall 110S of the base substrate 110, or may be a region with reduced surface roughness.

In some embodiments, a rounded chamfer portion 110R may be formed between the second surface 110F2 and the sidewall 110S of the base substrate 110 by the surface treatment process. For example, in the surface treatment process, the connection portion between the second surface 110F2 and the sidewall 110S of the base substrate 110 may be more exposed to the etching process or plasma process and thus more removed, thereby forming a rounded chamfer portion 110R at the edge of the base substrate 110.

In some embodiments, as the sidewall 110S of the base substrate 110 is exposed to an etching process or a plasma process by the surface treatment process to remove or planarize a portion of the sidewall 110S of the base substrate 110, a stepped portion ST may be formed in a boundary region between the sidewall 110S of the base substrate 110 and the sidewall 120S (see FIG. 2) of the device layer 120. For example, at least a portion of the sidewall 110S of the base substrate 110 in the stepped portion ST may be recessed inward by about 1 micrometer to about 5 micrometers from the sidewall 120S of the device layer 120.

In some embodiments, depending on the process conditions and properties of the surface treatment process, the portion of the sidewall 110S of the base substrate 110 adjacent to the device layer 120 may be less exposed to the etching atmosphere of the surface treatment process, and the portion of the sidewall 110S of the base substrate 110 adjacent to the device layer 120 may be removed by a smaller amount to form a tail portion TL (see FIG. 4). In this case, the semiconductor chip 100A described with reference to FIG. 4 may be formed.

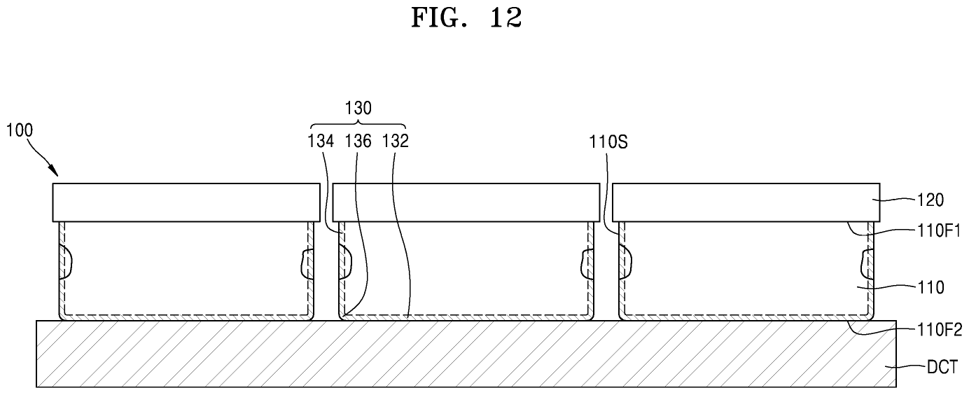

Referring to FIGS. 6 and 12, the plurality of semiconductor chips 100 may be packaged (operation P160).

In some embodiments, in the packaging operation of the plurality of semiconductor chips 100, first, a dicing tape DCT may be attached on the second surface 110F2 of the base substrate 110, and the plurality of semiconductor chips 100 may be flipped so that the device layer 120 of the semiconductor chip 100 faces upward.

The dicing tape DCT may include a base layer made of a polymer resin and an adhesive layer provided on one surface of the base layer. The base layer may be formed of, for example, polyvinyl chloride (PVC), polyolefin (PO), polyethylene terephthalate (PET), etc. In addition, the adhesive layer may be made of an acrylic resin or the like.

Thereafter, the plurality of semiconductor chips 100 may be packaged by performing processes including a wire bonding process, a molding process, a marking process, and a solder ball mounting process on the plurality of semiconductor chips 100.

In general, when a wafer is diced by stealth dicing technology, crack-causing defects may occur on the divided wafer surface, and these crack-causing defects may cause chipping or cracking of the package, thereby reducing the reliability of the package.

However, according to the embodiments described above, the stress relief regions 130 may be formed on the second surface 110F2 and the sidewall 110S of the base substrate 110 by performing a surface treatment process while the second surface 110F2 and the sidewall 110S of the base substrate 110 are exposed after the base substrate 110 is divided. Therefore, the reliability of the semiconductor package including the semiconductor chips 100 may be improved.

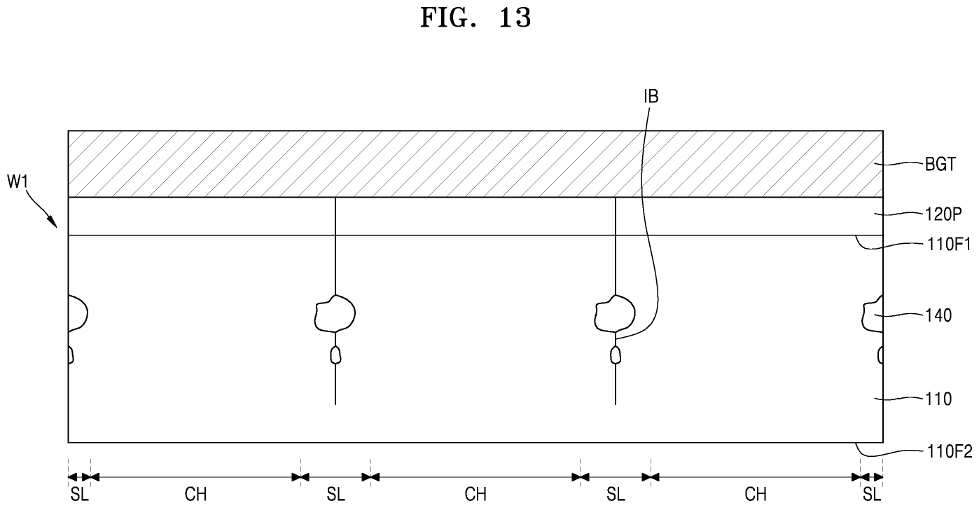

FIGS. 13 to 16 are schematic diagrams illustrating a method of manufacturing a semiconductor chip according to some embodiments.

First, a wafer W1 is prepared by performing the process described with reference to FIGS. 7A to 7C.

Referring to FIG. 13, a modified layer 140 and an internal crack IB may be formed in the wafer W1 by irradiating a laser beam L1 (see FIG. 8A) on the wafer W1.

In some embodiments, an additional cutting process may be performed before irradiating the laser beam L1 or after irradiating the laser beam L1. For example, the additional cutting process may be a process for forming a groove or recess in the device forming region 120P in the scribe lane region SL, and may include a laser grooving process or a blade cutting process. Thereafter, a protective tape BGT may be attached to the top surface of the wafer W1.

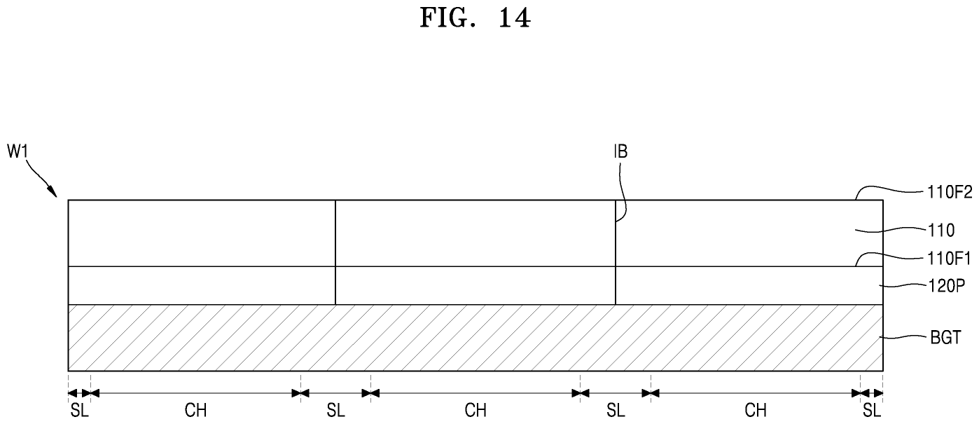

Referring to FIG. 14, the thickness of the base substrate 110 may be reduced from the second surface 110F2 of the base substrate 110 by grinding the bottom surface of the wafer W1.

In some embodiments, the grinding process may remove the modified layer 140 by a sufficient thickness of the base substrate 110 so that the modified layer 140 does not remain in the base substrate 110. All of the modified layers 140 may be removed by the grinding process, and the internal crack IB may remain in the base substrate 110.

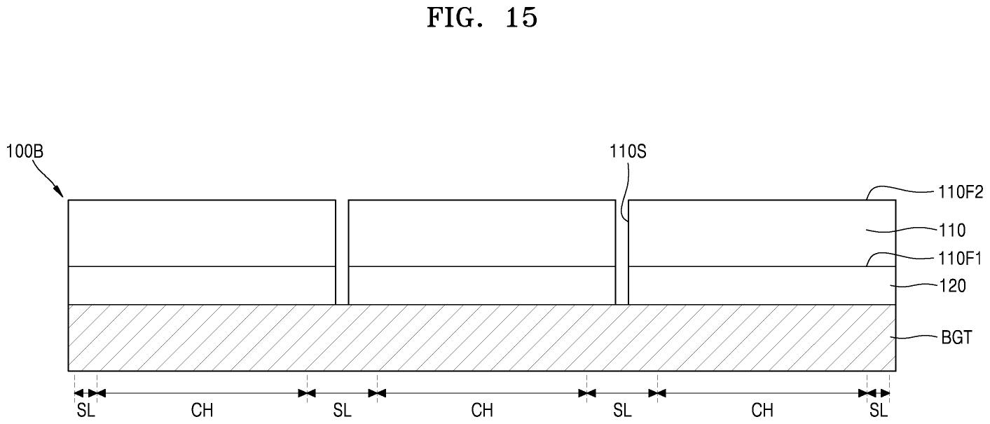

Referring to FIG. 15, a heat treatment process may be performed to extend the protective tape BGT and divide the wafer W1.

In some embodiments, by performing heat treatment on the protective tape BGT, the protective tape BGT may be extended to a certain width in the horizontal direction, and accordingly, the base substrate 110 may be divided or singulated along the internal crack IB. In this case, the wafer W1 may be singulated and separated into a plurality of semiconductor chips 100B by the internal crack IB in the scribe lane region SL.

In some embodiments, the plurality of semiconductor chips 100B may be arranged to be spaced apart in the horizontal direction (X direction or Y direction) while the sidewall 110S and the second surface 110F2 of the base substrate 110 are exposed, and the device layer 120 is attached to the protective tape BGT.

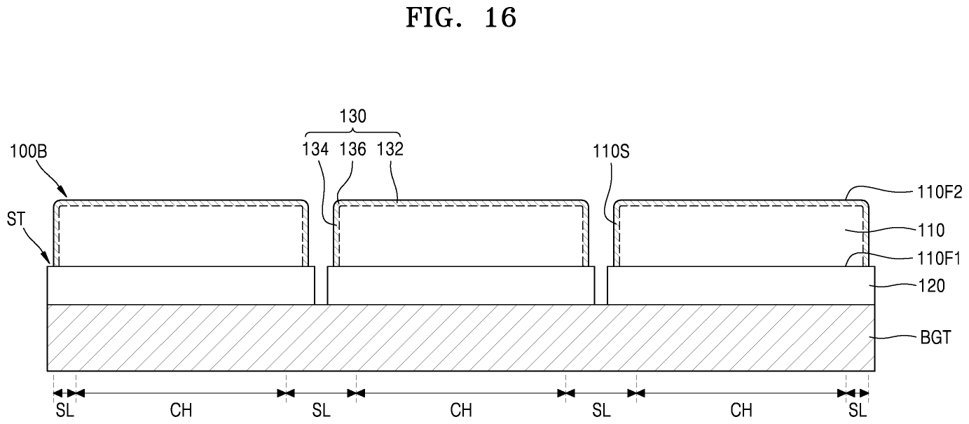

Referring to FIG. 16, a stress relief region 130 may be formed by performing a surface treatment process on the second surface 110F2 and the sidewall 110S of the base substrate 110.

In some embodiments, the surface treatment process may include at least one of a plasma etching process, a wet etching process, wet cleaning process, and the like. The surface treatment process may form a stress relief region 130 within a first depth dp1 (see FIG. 5) from the second surface 110F2 of the base substrate 110 and a second depth dp2 (see FIG. 5) from the sidewall 110S of the base substrate 110, and for example, the stress relief region 130 may indicate a region from which defect components such as a crack-causing defect or a chipping-causing defect present in a portion adjacent to the internal crack IB have been removed.

Thereafter, the plurality of semiconductor chips 100B may be packaged by performing the process described with reference to FIG. 12.

While the inventive concept has been particularly shown and described with reference to embodiments thereof, it will be understood that various changes in form and details may be made therein without departing from the spirit and scope of the following claims.

What is claimed is:

1. A semiconductor chip comprising:
a base substrate including a first surface, a second surface opposite to the first surface, and a sidewall extending between the first surface and the second surface; and
a device layer on the first surface of the base substrate, wherein
the base substrate includes a stress relief region within a first depth from the second surface and a second depth from the sidewall, and
at least a portion of the sidewall of the base substrate is recessed inward from a sidewall of the device layer.

2. The semiconductor chip of claim 1, wherein a stepped portion is defined in a boundary region between the at least a portion of the sidewall of the base substrate and the sidewall of the device layer.

3. The semiconductor chip of claim 1, wherein the base substrate includes:
a chip region; and
a scribe lane region surrounding the chip region, wherein
the stress relief region includes:
a rear region within the first depth from the second surface of the base substrate; and
a side region within the second depth from the sidewall of the base substrate, wherein
the side region is in the scribe lane region.

4. The semiconductor chip of claim 3, wherein a rounded chamfer portion is in a boundary region between the second surface of the base substrate and the sidewall of the base substrate.

5. The semiconductor chip of claim 4, wherein
the rear region of the stress relief region is connected to the side region of the stress relief region, and
a connection portion between the rear region and the side region extends along the shape of the rounded chamfer portion.

6. The semiconductor chip of claim 3, wherein
the base substrate includes a plurality of modified layers within the scribe lane region that are spaced apart from each other in a lateral direction, and
at least a portion of at least one of the plurality of modified layers vertically overlaps the stress relief region.

7. The semiconductor chip of claim 6, wherein
the base substrate includes single crystalline silicon, and
each of the plurality of modified layers includes amorphous silicon.

8. The semiconductor chip of claim 1, wherein the at least a portion of the sidewall of the base substrate is spaced apart from the sidewall of the device layer by a distance of about 1 micrometer to about 5 micrometers in a horizontal direction.

9. The semiconductor chip of claim 1, wherein a tail portion is in a boundary region between the sidewall of the base substrate and the sidewall of the device layer, the tail portion extending outwardly toward the sidewall of the base substrate.

10. A semiconductor chip comprising:
a base substrate including a chip region, a scribe lane region surrounding the chip region, and first and second surfaces opposite to each other; and
a device layer on the first surface of the base substrate, wherein
the base substrate includes a plurality of modified layers within the scribe lane region that are spaced apart from each other in a lateral direction, and at least a portion of a sidewall of the base substrate is recessed inward from a sidewall of the device layer.

11. The semiconductor chip of claim 10, wherein the base substrate further includes a stress relief region within a first depth from the second surface and a second depth from the sidewall thereof.

12. The semiconductor chip of claim 11, wherein the stress relief region includes:
a rear region within the first depth from the second surface of the base substrate; and
a side region within the second depth from the sidewall of the base substrate, wherein
the side region is in the scribe lane region.

13. The semiconductor chip of claim 12, wherein a rounded chamfer portion is in a boundary region between the second surface of the base substrate and the sidewall of the base substrate.

14. The semiconductor chip of claim 13, wherein
the rear region of the stress relief region is connected to the side region of the stress relief region, and
a connection portion between the rear region and the side region extends along the shape of the rounded chamfer portion.

15. The semiconductor chip of claim 14, wherein at least a portion of at least one of the plurality of modified layers vertically overlaps the side region of the stress relief region.

16. The semiconductor chip of claim 10, wherein
the base substrate includes single crystalline silicon, and
each of the plurality of modified layers includes amorphous silicon.

17. A semiconductor chip comprising:
a base substrate including a chip region, a scribe lane region surrounding the chip region, and first and second surfaces opposite to each other; and
a device layer on the first surface of the base substrate, wherein
the base substrate further includes:
a plurality of modified layers within the scribe lane region that are spaced apart from each other in a lateral direction;
a stress relief region within a first depth from the second surface and a second depth from a sidewall of the base substrate; and
a rounded chamfer portion in a boundary region between the second surface of the base substrate and the sidewall of the base substrate, wherein
at least a portion of the sidewall of the base substrate is horizontally offset inward from a sidewall of the device layer.

18. The semiconductor chip of claim 17, wherein the stress relief region includes:
a rear region within the first depth from the second surface of the base substrate; and
a side region within the second depth from the sidewall of the base substrate, wherein
the side region is in the scribe lane region, and
at least a portion of at least one of the plurality of modified layers vertically overlaps the side region of the stress relief region.

19. The semiconductor chip of claim 18, wherein
the rear region of the stress relief region is connected to the side region of the stress relief region, and
a connection portion between the rear region and the side region extends along a shape of the rounded chamfer portion.

20. The semiconductor chip of claim 17, wherein the at least a portion of the sidewall of the base substrate is spaced apart from the sidewall of the device layer by a distance of about 1 micrometer to about 5 micrometers in a horizontal direction.
